(19) United States
(12) Patent Application Publication
(10) Pub. No.: US 2023/0326843 A1
(43) Pub. Date: Oct. 12, 2023

(54) ELECTRIC CONTACT STRUCTURE FOR THREE-DIMENSIONAL CHIP PACKAGE MODULE

(71) Applicant: Chun-Hsia Chen, Taoyuan City (TW)

(72) Inventor: Chun-Hsia Chen, Taoyuan City (TW)

(21) Appl. No.: 17/715,056

(22) Filed: Apr. 7, 2022

(51) Int. Cl. H01L 23/498; H01L 25/065

(52) U.S. Cl. CPC H01L 23/49833; H01L 25/0657; H01L 2224/16227; H01L 24/16

(57) ABSTRACT

An electric contact structure includes an intermediate plate, spacer bars and a carrier plate. The spacer bars are sandwiched between the intermediate plate and the carrier plate. Wires are embedded in the intermediate plate, the spacer bars and the carrier plate. The wires in the spacer bars connect the wires in both the intermediate plate and the carrier plate to compose a three-dimensional connecting circuit. At least one end of each of the wires in the spacer bars is formed with a protrusive contact. An end of each of the wires in the intermediate plate or the carrier plate is formed with a cavity. The bottom of each cavity is provided with a disk contact connecting with one of the wires. Each protrusive contact is embedded into one of the cavities to form electric connection with corresponding one of the disk contacts.

### BACKGROUND

### Technical Field

The invention relates to chip package structures, particularly to an improved electric contact structure for three-dimensional chip package module.

### Related Art

A three-dimensional chip package structure has advantages of saving chip package costs, increasing the yield rate of packaged products, increasing the disposing density of packaged elements and shrinking the volume of packaged products. As shown in FIGS. 8 and 9, in a prior art three-dimensional chip package structure, an end of each of wires 21, 31 in an intermediate plate, a spacer bar 2 and a carrier plate 3 is formed with a protrusive contact P so that two adjacent protrusive contacts are melted to form an effective electric connection when the layers are laminated. However, when two protrusive contacts are melted to connect, the melted metal material tends to expand outward. Because of the capillary action, the melted metal material will overflow along the gap at the junctions to connect adjacent contacts to cause short.

### SUMMARY

An object of the invention is to provide an improved electric contact structure for three-dimensional chip package module, which can prevent the melted metal from overflowing to cause short.

Another object of the invention is to provide an improved electric contact structure for three-dimensional chip package module, which makes the contacts formed by the melted metal have firm structure, high strength and shock and vibration resistance.

To accomplish the above object, the invention provides an improved electric contact structure for three-dimensional chip package module, which includes an intermediate plate, spacer bars and a carrier plate. The spacer bars are superposed on the intermediate plate. The carrier plate is superposed on the spacer bars. Wires are embedded in the intermediate plate, the spacer bars and the carrier plate. The wires in the spacer bars connect the wires in both the intermediate plate and the carrier plate to compose a three-dimensional connecting circuit. At least one end of each of the wires in the spacer bars is formed with a protrusive contact. An end of each of the wires in the intermediate plate or the carrier plate is formed with a cavity. The bottom of each cavity is provided with a disk contact connecting with one of the wires. Each protrusive contact is embedded into one of the cavities to form electric connection with corresponding one of the disk contacts when the intermediate plate, the spacer bars and the carrier plate are laminated.

In the present invention, the protruding length of each protrusive contact is greater than the depth of each cavity, and the cavity is of a conic shape, a rod shape or a spot face shape.

### BRIEF DESCRIPTION OF THE DRAWINGS

FIG. 1 is a top plan view of the three-dimensional chip package module of the invention;

FIG. 2 is a cross-sectional view along line II-II in FIG. 1;

FIG. 3 is a plan view of the spacer bar of the invention;

FIG. 4 is a plan view of the carrier plate of the invention;

FIG. 5 is an enlarged view of part A of FIG. 2, which shows the contact structure between the spacer bar and the carrier plate of the invention;

FIG. 6 is an exploded view of the contact structure of the invention;

FIG. 7 is a schematic view of the contact structure between the spacer bar and the intermediate plate of the invention;

FIG. 8 is a cross-sectional view of a prior art contact structure between a spacer bar and a carrier plate; and

FIG. 9 is an exploded view of the prior art contact structure shown in FIG. 8.

### DETAILED DESCRIPTION

The technical contents of this disclosure will become apparent with the detailed description of embodiments accompanied with the illustration of related drawings as follows. It is intended that the embodiments and drawings disclosed herein are to be considered illustrative rather than restrictive.

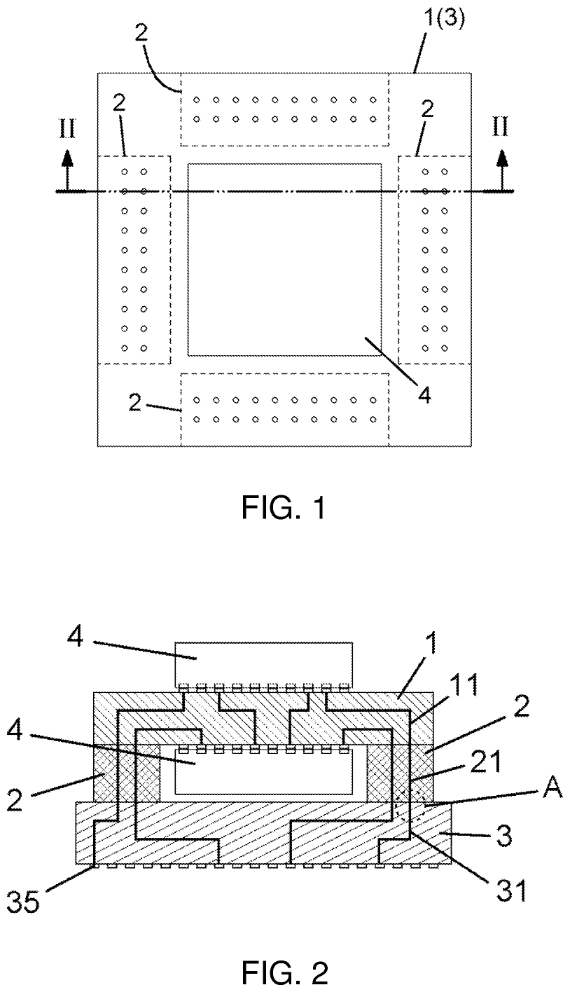

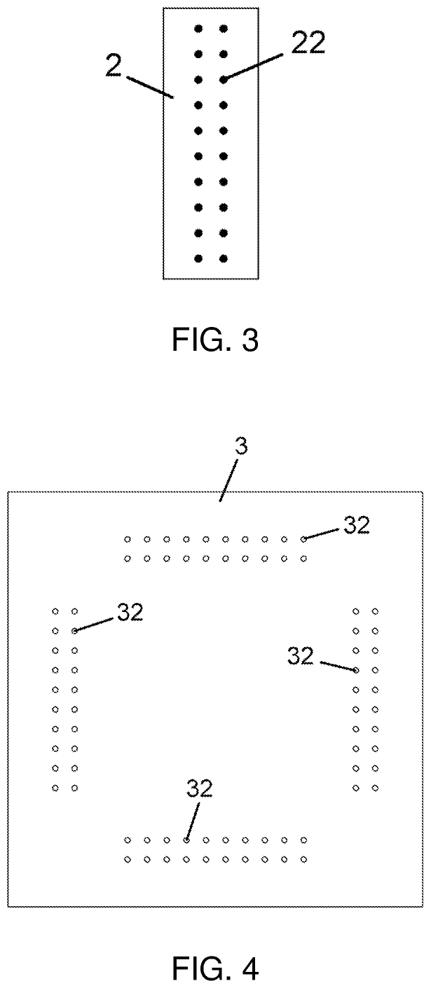

Please refer to FIGS. 1-4, which shows the simplest embodiment of the invention. The invention provides an improved electric contact structure for three-dimensional chip package module, which includes an intermediate plate 1, four spacer bars 2 and a carrier plate 3. The spacer bars 2 are superposed on the intermediate plate 1 and the carrier plate 3 is superposed on the spacer bars 2, so that the spacer bars 2 are sandwiched between the intermediate plate 1 and the carrier plate 3. Wires 11, 21, 31 are embedded in the intermediate plate 1, the spacer bars 2 and the carrier plate 3. The wires 21 in the spacer bars 2 connect the wires 11, 31 in both the intermediate plate 1 and the carrier plate 3 to compose a three-dimensional connecting circuit. A semiconductor chip 4 is assembled on an upper surface and/or a lower surface of the intermediate plate 1 and is electrically connected to the wires 11. Signals of the semiconductor chip 4 can be connected to outer contacts 35 on the bottom of the carrier plate 3 by the signal transmission via the three-dimensional connecting circuit.

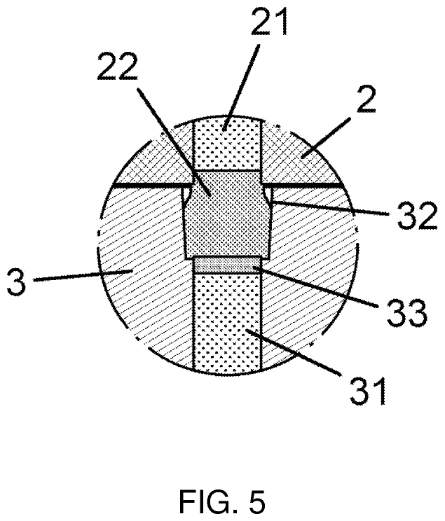

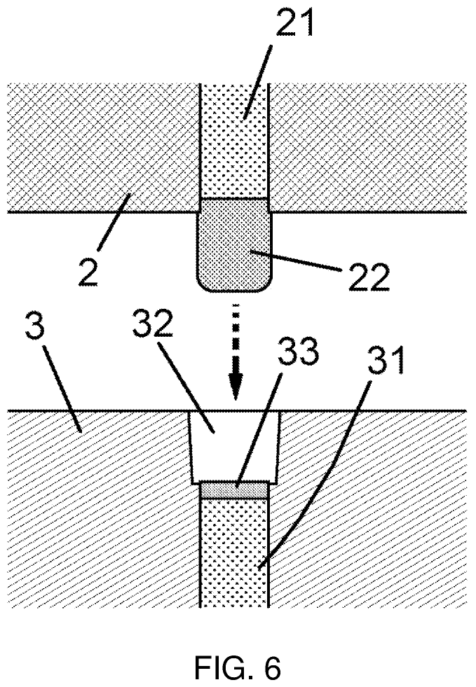

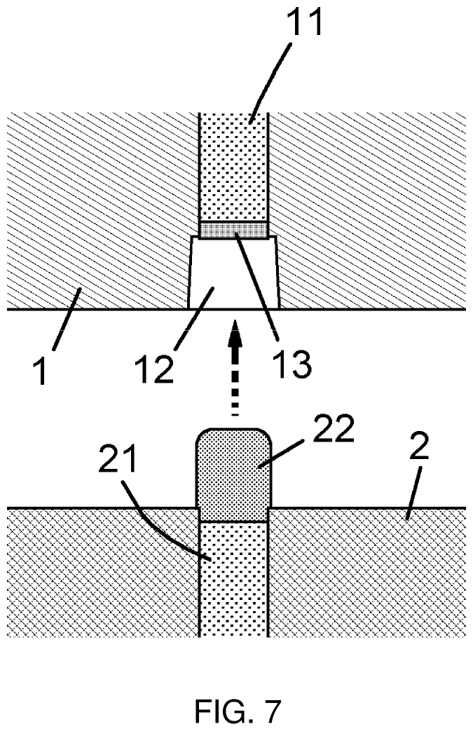

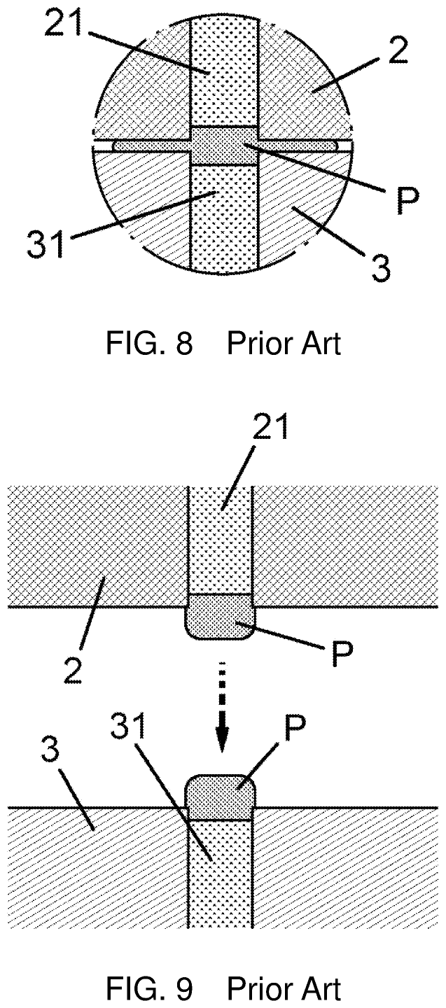

FIGS. 5 and 6 show the contact structure of the invention. An end of each of the wires 21 in the spacer bars 2 is formed with a protrusive contact 22. An end of each of the wires 31 in the carrier plate 3 is formed with a cavity 32. The bottom of each cavity 32 is provided with a disk contact 33 connecting with one of the wires 31. Optionally, as shown in FIG. 7, the other end of each of the wires 21 in the spacer bars 2 is formed with a protrusive contact 22, and an end of each of the wires 11 in the intermediate plate 1 is formed with a cavity 12. The bottom of each cavity 12 is provided with a disk contact 13 connecting with one of the wires 11. The cavities 12, 32 in the intermediate plate 1 and the carrier plate 3 may coexist. The protruding length of each protrusive contact 22 must be greater than the depth of each cavity 12, 32 to prevent the protrusive contacts 22 and the disk contacts 13, 33 from forming poor electric connections. The cavity 12, 32 may be of a rod shape, a spot face shape or any other shapes, and a conic shape is preferred because a cone-shaped cavity is advantageous to embedding the protrusive contact into the cavity 32 to guarantee a good electric connection formed between the protrusive contact 22 and the disk contact 13, 33.

Each protrusive contact 22 is embedded into one of the cavities 12, 32 to be melted to form electric connection with corresponding one of the disk contacts 13, 33 in the cavities 12, 32 when the intermediate plate 1, the spacer bars 2 and the carrier plate 3 are laminated. The contact structure utilizes the cavity 12, 32 to accommodate the protrusive contact 22 to prevent melted metal from overflowing to cause short. And, the contacts formed by the melted metal have firm structure, high strength and shock and vibration resistance.

The contact structure in the above embodiment may also be applied to a junction between the chip 4 and the intermediate plate 1. In other embodiments, the protrusive contact may also be disposed in the carrier plate 3 and/or the intermediate plate 1 and the cavity is disposed in the spacer bars 2.

While this disclosure has been described by means of specific embodiments, numerous modifications and variations could be made thereto by those skilled in the art without departing from the scope and spirit of this disclosure set forth in the claims.

What is claimed is:

1. An electric contact structure for three-dimensional chip package module, comprising:
an intermediate plate;
spacer bars, superposed on the intermediate plate; and
a carrier plate, superposed on the spacer bars;
wherein wires are embedded in the intermediate plate, the spacer bars and the carrier plate, the wires in the spacer bars connect the wires in both the intermediate plate and the carrier plate to compose a three-dimensional connecting circuit, at least one end of each of the wires in the spacer bars is formed with a protrusive contact, an end of each of the wires in the intermediate plate or the carrier plate is formed with a cavity, a bottom of each cavity is provided with a disk contact connecting with one of the wires, and each protrusive contact is embedded into one of the cavities to form electric connection with corresponding one of the disk contacts when the intermediate plate, the spacer bars and the carrier plate are laminated.

2. The electric contact structure for three-dimensional chip package module of claim 1, wherein a protruding length of each protrusive contact is greater than a depth of each cavity.

3. The electric contact structure for three-dimensional chip package module of claim 2, wherein the cavity is of a conic shape, a rod shape or a spot face shape.
